(19) United States
(12) Patent Application Publication
(10) Pub. No.: US 2025/0275454 A1
(43) Pub. Date: Aug. 28, 2025

(54) DISPLAY DEVICE

(71) Applicant: LG Display Co., Ltd., Seoul (KR)

(72) Inventor: KeumYoung Oh, Gumi-si (KR)

(73) Assignee: LG Display Co., Ltd., Seoul (KR)

(21) Appl. No.: 19/016,270

(22) Filed: Jan. 10, 2025

(30) Foreign Application Priority Data
Feb. 27, 2024 (KR) 10-2024-0027965

(51) Int. Cl. H10K 59/80

(52) U.S. Cl. CPC H10K 59/8792; H10K 59/872; H10K 59/8793

(57) ABSTRACT

According to an aspect of the present disclosure, a display device includes a display panel including a plurality of sub pixels; dual glasses disposed on the display panel and including an upper glass and a lower glass; and a polarization layer disposed between the upper glass and the lower glass, wherein the dual glasses include an active area and a non-active area, and the polarization layer may be disposed from the active area to the non-active area.

### CROSS-REFERENCE TO RELATED APPLICATION

This application claims the priority of Korean Patent Application No. 10-2024-0027965, filed on Feb. 27, 2024, in the Korean Intellectual Property Office, the disclosure of which is incorporated herein by reference.

### BACKGROUND

The present disclosure relates to a display device and, more particularly, to a display device in which a boundary between a non-active area and an active area is not visible or less visible.

### DESCRIPTION OF THE RELATED ART

Currently, as it enters a full-scale information era, a field of a display device which visually expresses electrical information signals has been rapidly developed and studies are continued to improve performances of various display devices such as a small thickness, a light weight, and low power consumption.

As a representative display device, there are a liquid crystal display device (LCD), an electro-wetting display device (EWD), an organic light emitting display device (OLED), etc.

Among them, an electroluminescent display device including an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

### SUMMARY

An object to be achieved by the present disclosure is to provide a display device which includes a polarization layer extending from an active area to a non-active area so that the boundary between the non-active area and the active area is not visible.

Objects of the present disclosure are not limited to the above-mentioned objects, and other objects, which are not mentioned above, can be clearly understood by those skilled in the art from the following descriptions.

To achieve these and other objects of the present disclosure, and according to an aspect of the present disclosure, a display device includes a display panel including a plurality of sub pixels; dual glasses disposed on the display panel and including an upper glass and a lower glass; and a polarization layer disposed between the upper glass and the lower glass, wherein the dual glasses include an active area and a non-active area, and the polarization layer may be disposed from the active area to the non-active area.

Other detailed matters of example embodiments are included in the detailed description and the drawings.

According to an aspect of the present disclosure, a polarization layer which is disposed not only in the active area but also in the non-active area is provided to implement a boundary between the active area and the non-active area seamlessly without increasing a surface reflectance.

According to an aspect of the present disclosure, a polarization layer disposed in the active area and the non-active area is provided to provide substantially equivalent or uniform visibility to an entire area, that is, an area including the active area and the non-active area by the polarization layer.

According to an aspect of the present disclosure, the boundary between the active area and the non-active area is seamlessly implemented while the display device displays black.

The effects according to the present disclosure are not limited to the contents exemplified above, and more various effects are included in the present specification.

Additional features and aspects of the present disclosure are set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the present disclosure and are incorporated in and constitute a part of this application, illustrate aspects of the disclosure and together with the description serve to explain various principles of the present disclosure. In the drawings:

FIG. 1 is a schematic diagram of a display device according to an example embodiment of the present disclosure;

FIG. 2 is a circuit diagram of a sub pixel according to an example embodiment of the present disclosure;

FIG. 3 is an exploded perspective view of a display device according to an example embodiment of the present disclosure;

FIG. 4A is a plan view of a display device according to an example embodiment of the present disclosure; and

FIG. 4B is a cross-sectional view taken along the line A-A′ of FIG. 4A.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including’, ‘having’, ‘consist of’ used herein are generally intended to allow other components to be added unless the terms are used with a more limiting term like ‘only’. Any references to singular may include plural unless, and vice versa, expressly stated otherwise.

Components are interpreted to include an ordinary error range even if not expressly stated.

Where the position relation between two parts is described using the terms such as ‘on’, ‘above’, ‘below’, ‘next’, one or more parts may be positioned between the two parts unless the terms are used with a more limiting term like ‘immediately’ or ‘directly’.

Where an element or layer is disposed “on” another element or layer, another layer or another element may be interposed directly on the other element or therebetween.

In addition, where components are described as ‘coupled’ or ‘connected’, it may include being ‘coupled’ or ‘connected’ through one or more other components located between the two components, unless a more limiting term like ‘immediately’ or ‘directly’ is used.

Although the terms “first”, “second”, and the like may be used for describing various components, these components are not confined by these terms. These terms are merely used for referring to one component separately from the other components. Therefore, a first component to be mentioned below may be a second component, and vice versa, in a technical concept of the present disclosure.

Like reference numerals generally denote like elements throughout the specification unless otherwise specified.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

A transistor used for a display device according to example embodiments of the present disclosure may be implemented by any one transistor of n-channel transistors (NMOS) and p-channel transistors (PMOS). The transistor may be implemented by an oxide semiconductor transistor having an oxide semiconductor as an active layer or an LTPS transistor having a low temperature polysilicon (LTPS) as an active layer. The transistor may include at least a gate electrode, a source electrode, and a drain electrode. The transistor may be implemented as a thin film transistor (TFT) on a display panel. In the transistor, carriers flow from the source electrode to the drain electrode. In the case of the n-channel transistor NMOS, since the carriers are electrons, to allow the electrons to flow from the source electrode to the drain electrode, a source voltage may be lower than a drain voltage. The current in the n-channel transistor NMOS flows from the drain electrode to the source electrode and the source electrode may serve as an output terminal. In the case of the p-channel transistor PMOS, since the carriers are holes, to allow the holes to flow from the source electrode to the drain electrode, a source voltage is higher than a drain voltage. In the p-channel transistor PMOS, the holes flow from the source electrode to the drain electrode so that current flows from the source electrode to the drain electrode and the drain electrode serves as an output terminal. Accordingly, it should be noted that the source and the drain may be switched in accordance with the applied voltage so that the source and the drain of the transistor are not fixed. In the present specification, it is assumed that the transistor is an n-channel transistor NMOS, but is not limited thereto so that the p-channel transistor may be used and thus a circuit configuration may be changed.

A gate signal of transistors which are used as switching elements swings between a gate-on voltage and a gate-off voltage. The gate-on voltage is set to be higher than a threshold voltage Vth of the transistor and the gate off voltage may be set to be lower than the threshold voltage Vth of the transistor. The transistor is turned on in response to the gate-on voltage and may be turned off in response to the gate-off voltage. In the case of the n-channel transistor NMOS, the gate-on voltage is a gate high voltage VGH and the gate-off voltage is a gate low voltage VGL. In the case of the p-channel transistor PMOS, the gate-on voltage is a gate low voltage VGL, and the gate-off voltage may be a gate high voltage VGH.

Hereinafter, various embodiments of the present disclosure will be described in detail with reference to accompanying drawings.

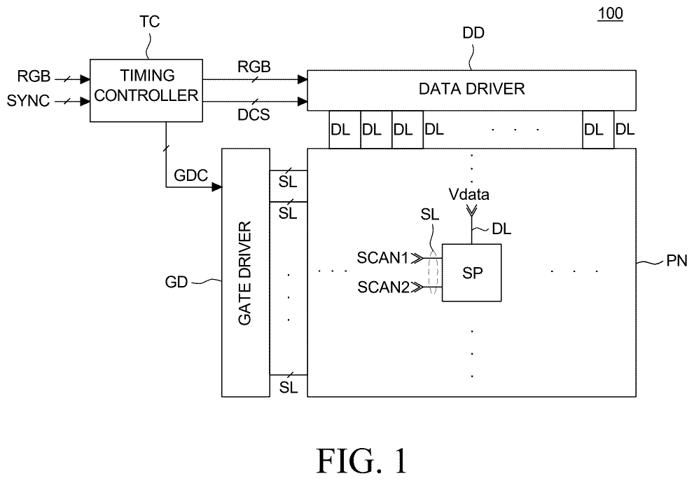

FIG. 1 is a schematic diagram of a display device according to an example embodiment of the present disclosure.

As shown in FIG. 1, a display device 100 of a first example embodiment of the present disclosure includes a display panel PN including a plurality of sub pixels SP, a gate driver GD and a data driver DD which supply various signals to the display panel PN, and a timing controller TC which controls the gate driver GD and the data driver DD.

The gate driver GD may supply a plurality of scan signals to a plurality of scan lines SL in accordance with a plurality of gate control signals GCS supplied from the timing controller TC. The plurality of scan signals may include a first scan signal SCAN1 and a second scan signal SCAN2.

The data driver DD may convert image data RGB input from the timing controller TC in accordance with a plurality of data control signals DCS supplied from the timing controller TC into a data signal Vdata using a reference gamma voltage. Further, the data driver DD may supply the converted data signal Vdata to the plurality of data lines DL.

The timing controller TC aligns image data RGB which is input from the outside to supply the image data to the data driver DD and may generate a gate control signal GCS and a data control signal DCS using a synchronization signal SYNC input from the outside.

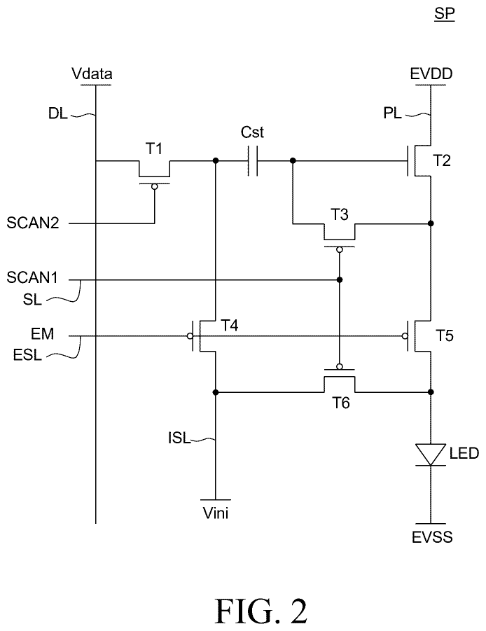

FIG. 2 is a circuit diagram of a sub pixel according to an example embodiment of the present disclosure.

As shown in FIG. 2, the pixel circuit of each of the plurality of sub pixels SP may include first to sixth transistors T1, T2, T3, T4, T5, and T6 and a capacitor Cst.

The first transistor T1 is connected to a second scan line to be controlled by a second scan signal SCAN2 supplied through the second scan line. The first transistor T1 may be electrically connected between a data line which supplies a data signal Vdata and the capacitor Cst.

The second transistor T2 may be electrically connected between the high potential power line to which a high potential power signal EVDD is supplied and the fifth transistor T5. Further, a gate electrode of the second transistor T2 may be electrically connected to the capacitor Cst.

Further, the third transistor T3 may be controlled by a first scan signal SCAN1 supplied through the first scan line and compensate for a threshold voltage of the second transistor T2 and the third transistor T3 may be referred to as a compensation transistor.

The fourth transistor T4 may be electrically connected to the capacitor Cst and an initialization signal line to which an initialization signal Vini is supplied. Further, the fourth transistor T4 may be controlled by an emission control signal EM supplied through the emission control signal line.

Further, the fifth transistor T5 is electrically connected between the second transistor T2 and the light emitting diode LED and may be controlled by the emission control signal EM supplied through the emission control signal line.

The sixth transistor T6 is electrically connected between the initialization signal line through which the initialization signal Vini is supplied and an anode of the light emitting diode LED and may be controlled by the first scan signal SCAN1 supplied through the first scan line.

It has been described above that the pixel circuit of each of the plurality of sub pixel SP is configured to include the first to sixth transistors T1, T2, T3, T4, T5, and T6 and the capacitor Cst as an example, but the present disclosure is not limited as described above.

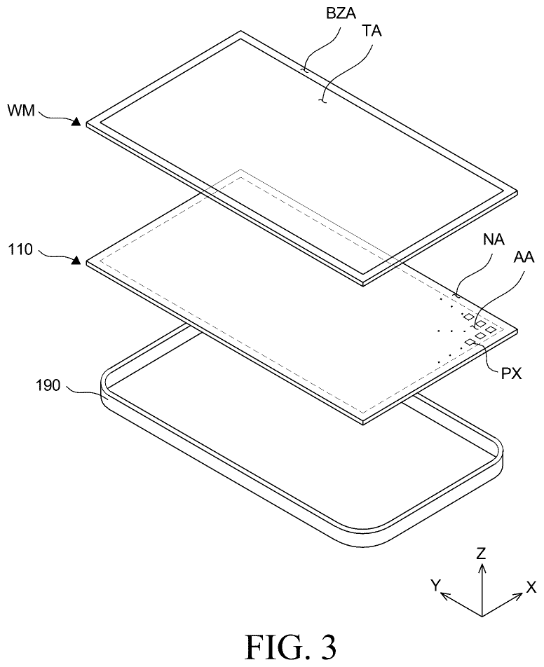

FIG. 3 is an exploded perspective view of a display device according to an example embodiment of the present disclosure.

FIG. 3 is an exploded perspective view of a display device according to an example embodiment. The display device 100 may include a display panel 110 and a window WM disposed on at least one of a top and a bottom of the display panel 110. In FIG. 3, it is illustrated that the window WM is disposed on the top of the display panel 110, but it is illustrative and the window WM may be disposed on both the top and the bottom of the display panel 110.

Further, the display device 100 may further include a housing 190 in which the display panel 110 is accommodated. In the display device 100, the window WM and the housing 190 are coupled to configure an external appearance of the display device 100. The housing 190 is disposed below the display panel 110. The housing 190 includes a material having a higher rigidity. For example, the housing 190 may include a plurality of frames and/or plates configured by glass, plastic, or metal. The housing 190 may provide a predetermined accommodation space. The display panel 110 is accommodated in the accommodation space to be protected from the external shock.

The display panel 110 may be activated according to an electrical signal. The display panel 110 is activated to display an image on a display surface of the display device 100. Further, the display panel 110 is activated to sense an external input applied to an upper surface. The external input may include a user's touch, contact or proximity with an intangible object, pressure, light, or heat, but is not limited to any one example.

The display panel 110 may include an active area AA and a non-active area NA. The active area AA may be an area where images are provided. A pixel PX may be disposed in the active area AA. The non-active area NA may be adjacent to the active area AA. The non-active area NA encloses the active area AA. In the non-active area NA, driving circuits or driving lines for driving the active area AA may be disposed.

The display panel 110 may include a plurality of pixels PX. Each of the pixels PX may display light in response to the electrical signal. Light displayed by the pixels PX may implement images. Each of the pixels PX may include a display element. For example, the display element may be an organic light emitting diode, a quantum dot light emitting diode, an electrophoretic element, an electrowetting element, etc.

The window WM may include a transmissive area TA and a bezel area BZA. The transmissive area TA may overlap at least a part of the active area AA of the display panel 110. The transmissive area TA may be an optically transparent area. For example, the transmissive area TA may have a transmittance of approximately 90% or more with respect to a wavelength of a visible ray region. The image is provided to a user through the transmissive area TA and the user may receive information through the image.

The bezel area BZA is an area having a light transmittance lower than that of the transmissive area TA. The bezel area BZA may define a shape of the transmissive area TA. The bezel area BZA is adjacent to the transmissive area TA and may enclose the transmissive area TA.

The bezel area BZA may have a predetermined color. The bezel area BZA covers the non-active area NA of the display panel 110 to block the non-active area NA from being visibly recognized from the outside. In the meantime, this is illustrative and in the window WM according to the example embodiment, the bezel area BZA may be omitted.

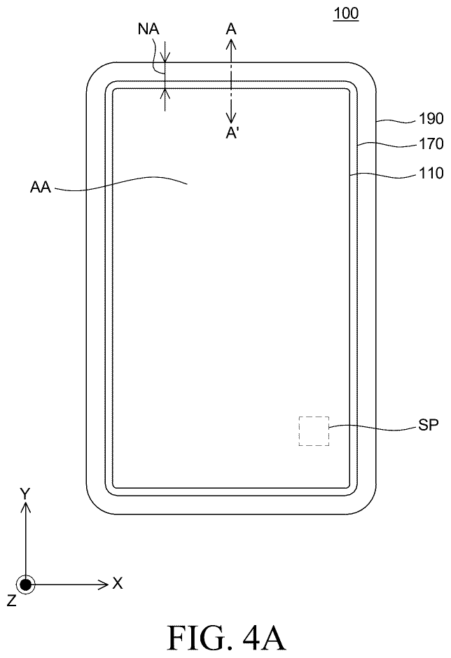

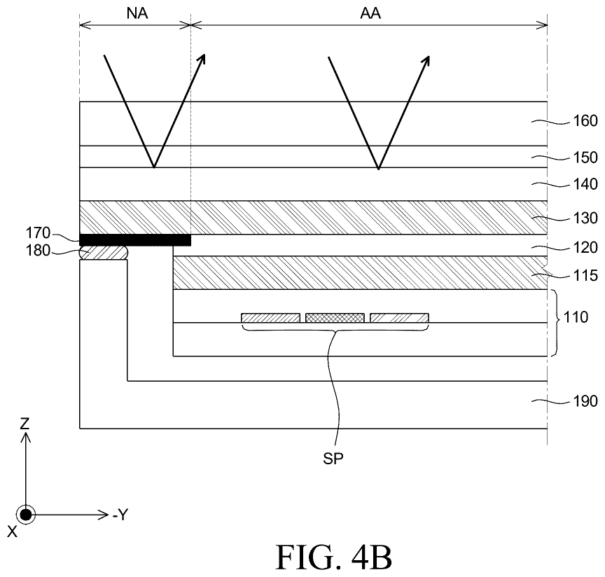

FIG. 4A is a plan view illustrating a display device according to an example embodiment of the present disclosure. FIG. 4B is a cross-sectional view taken along the line A-A′ of FIG. 4A.

As shown in FIGS. 4A and 4B, the display device 100 may include a display panel 110. The display panel 110 of the display device 100 is a panel in which images are implemented. Display elements for implementing images, and circuits, wiring lines, and components for driving the display elements may be disposed in the display panel. The display panel 110 may include an active area AA and a non-active area NA.

The active area AA is an area where a plurality of sub pixels SP is disposed to display images. Each of the plurality of sub pixels is an individual unit which emits light. In each of the plurality of sub pixels, a light emitting diode and a driving circuit may be formed. In the plurality of sub pixels, the display elements for displaying images and circuit units (e.g. circuits, wiring lines, and components) for driving the display elements may be disposed. For example, when the display device 100 is an organic light emitting display device, the display element may include an organic light emitting display element and when the display device 100 is a liquid crystal display device, the display element may include a liquid crystal element. The plurality of sub pixels may include a red sub pixel, a green sub pixel, a blue sub pixel and/or a white sub pixel, but is not limited thereto.

The non-active area NA is an area where no image is displayed.

The non-active area NA may enclose the active area AA. To be more specific, the non-active area NA is an area which encloses the periphery of the active area AA and does not display information. The non-active area NA may define an outer periphery of the display device while enclosing the edge of active area AA.

In FIG. 4A, it is illustrated that the non-active area NA encloses a rectangular active area AA, Shapes and placement of the active area AA and the non-active area NA are not limited to an example illustrated in FIG. 4A.

The active area AA and the non-active area NA may have shapes suitable for a design of an electronic device including the display device 100. For example, another example shape of the active area AA may be a pentagon, a hexagon, a circle, or an oval.

In the non-active area NA, various wiring lines and circuits for driving the organic light emitting diode of the active area AA may be disposed. For example, in the non-active area NA, a link line which transmits signals to the plurality of sub pixels and circuits of the active area AA or a driving IC such as a gate driver IC or a data driver IC may be disposed, but it is not limited thereto.

Further, the display panel 110 may selectively further include a sensor area. The sensor area may be disposed in the active area AA. In the active area AA, the sensor area (or a camera area) may be disposed between the plurality of sub pixels. The sensor area may be an area in which an optical sensor component, such as a camera or a proximity sensor, is disposed. The sensor area may include a through hole (or a hole) which passes through some configurations of the display device 100 to dispose the optical components. The through hole which passes through the display panel 110 is formed to ensure a space in which the optical sensor component is disposed.

In the meantime, a left side and/or a right side of the display device 100 may be defined as a gate pad unit in which a gate driver IC is disposed and an upper side and/or a lower side of FIG. 4A may be defined as a data pad unit to which a flexible film is connected, but is not limited thereto.

At this time, the gate driver IC is independently formed from the display panel PN to be electrically connected to the display panel 100 in various methods, but may also be configured as a gate in panel (GIP) to be mounted in the display panel 110.

The display device 100 may include various additional elements to generate various signals or drive the pixel in the active area AA. The additional elements for driving the pixels may include an inverter circuit, a multiplexer, or an electrostatic discharge circuit (ESD). The display device 100 may further include an additional element associated with a function other than a function of driving a pixel. For example, the display device 100 may include additional elements which provide a touch sensing function, a user authentication function (for example, fingerprint recognition), a multilevel pressure sensing function, or a tactile feedback function. The additional elements may be located in an external circuit which is connected to the non-active area NA and/or the connecting interface.

Even though it is not illustrated, the flexible film is a film which supplies a signal to the plurality of sub pixels and the circuits of the active area AA and may be electrically connected to the display panel 110. The flexible film is disposed at one end of the non-active area NA of the display panel 110 to supply a power voltage or a data voltage to the plurality of sub pixels and the circuits of the active area AA. For example, a driving IC such as a data driver IC may be disposed in the flexible film.

The printed circuit board is disposed at one end of the flexible film to be connected to the flexible film. The printed circuit board is a component which supplies signals to the driving IC. The printed circuit board may supply various signals such as a driving signal or a data signal to the driving IC.

As shown in FIG. 4B again, the display device 100 may include a sensor layer 115. The sensor layer 115 may be disposed on the top of the display panel 110. The sensor layer 115 may be configured by a touch sensor. The sensor layer 115 may detect the presence of touch and a touch coordinate based on a change in a capacitance between the touch electrodes or a capacitance between a touch electrode and a pointer (for example, a finger), through a plurality of touch electrodes. The sensor layer 115 may be disposed as an in-cell or an on-cell type. The sensor layer 115 may be manufactured together when the display panel 110 is manufactured.

To be more specific, the plurality of sub pixels SP is disposed on the substrate and an encapsulation layer may be disposed on an organic emission layer and an electrode layer of a light emitting diode disposed in each of the plurality of sub pixels SP. Further, the sensor layer 115 may be disposed on the encapsulation layer. The plurality of touch electrodes may be disposed as a touch on encapsulation (ToE) type. However, a shape of the sensor layer 115 is not limited to the above-described type, but may vary depending on the necessity of the design.

Even though it is not illustrated, the touch driver is electrically connected to the sensor layer to determine whether the user touches and a touch position. That is, when the user touches a part of the display panel 110, the touch driver senses a touch signal of the sensor layer 115 to determine whether the user touches the display panel 110 and a touch position.

In the meantime, the display device 100 according to the example embodiment of the present disclosure does not include a sensor layer 115 depending on a type of the display device and a design manner. For example, in FIG. 4B, the sensor layer 115 may not be disposed between the display panel 110 and a first adhesive member 120 to be described below, but is not limited thereto.

The display device 100 may include adhesive members 120 and 150. The adhesive members 120 and 150 may be configured by transparent adhesive members. For example, the adhesive members 120 and 150 may be formed of a material such as an optical clear adhesive (OCA), optical clear resin (OCR), or a pressure sensitive adhesive (PSA), or may include them.

The adhesive members 120 and 150 may include a first adhesive member 120 and a second adhesive member 150.

The first adhesive member 120 may bond the display panel 110 and a lower glass 130. To be more specific, the first adhesive member 120 may bond the sensor layer 115 above the display panel 110 and the lower glass 130.

The second adhesive member 150 may bond the polarization layer 140 and an upper glass 160.

The display device 100 may include a window (the window WM of FIG. 3). The window WM may include dual glasses 130 and 160. The dual glasses 130 and 160 may include an upper glass 160 and a lower glass 130. The upper glass 160 may be disposed above the lower glass 130. The dual glasses 130 and 160 may protect the display panel 110 from the external impact, as cover glasses of the display panel 110. As the glass which serves as a cover glass is configured as a double-layered structure so that the impact resistance from the outside may be improved.

In the meantime, the upper glass 160 is formed of glass which is tempered to protect the display panel 110 so that the lower glass 130 may not be tempered. Thus, a strength of the upper glass 160 is higher than a strength of the lower glass 130. As illustrated in FIG. 4, the upper glass 160 may be a configuration which is more adjacent to the outside of the display device than the lower glass 130. Therefore, the upper glass 160 is stronger than the lower glass 130 and is formed to be thicker to protect the display panel 110 from the external impact.

At this time, the lower glass 130 may be protected from the external impact by the upper glass 160 so that impact weaker than the upper glass 160 may be transmitted to the lower glass 130. Therefore, the tempering treatment for the lower glass 130 may be omitted so that the tempering cost may be minimized or reduced.

The dual glasses 130 and 160 may include an active area AA and a non-active area NA. To be more specific, the dual glasses 130 and 160 may be disposed in both the active area AA and the non-active area NA. The dual glasses 130 and 160 are disposed from an active area AA to a non-active area NA to cover the entire area of the display device.

In the meantime, the sensor layer 115 may be bonded to the lower glass 130. The sensor layer 115 and the lower glass 130 may be bonded by the second adhesive member 150.

The display device may include a light shielding member 170. The light shielding member 170 may include black ink, but is not limited thereto. The light shielding member 170 is applied or printed on a rear surface of the lower glass 130. The light shielding member 170 may be located in the non-active area NA. The light shielding member 170 may shield light which is incident into the non-active area NA or light which is incident into the active area AA through the non-active area NA. In the example embodiment of the present disclosure, the non-active area NA may be defined as an area where the light shielding member 170 is disposed, and in this case, the non-active area NA may be referred to as a bezel area.

The display device may include a polarization layer 140. The polarization layer 140 may be disposed between the upper glass 160 and the lower glass 130. That is, the polarization layer 140 may be disposed between the dual glasses 130 and 160.

The polarization layer 140 may be disposed from the active area AA to the non-active area NA. As the polarization layer 140 extends to the non-active area NA, light which enters from the outside may be substantially equally or uniformly polarized and reflected from the active area AA and the non-active area NA. Light which enters from the outside may be substantially equally or uniformly polarized and reflected and it is difficult for the user to recognize a boundary between the active area AA and the non-active area NA. To be specific, when a black screen is displayed or no arbitrary screen is displayed, the boundary between the active area AA and the non-active area NA may not be visible.

The polarization layer 140 may be disposed above the light shielding member 170. The polarization layer 140 is disposed above the light shielding member 170 in the non-active area NA and may reflect incident light before the light shielding member 170. Typically, the boundary between the non-active area NA and the active area AA is caused by the difference of the visibility of the light shielding member 170 and the polarization layer 140 disposed in the non-active area NA. The polarization layer 140 according to the example embodiment of the present disclosure covers the top of the light shielding member 170 so that a part of light which is incident from the outside is polarized and reflected by the polarization layer 140 before being reflected by the light shielding member 170. Accordingly, the difference in visibility between the active area AA and the non-active area NA may be minimized or reduced.

There is no additional polarization layer 140 between the light shielding member 170 and the display panel 110. In other words, there is no additional polarization layer 140 between the display panel 110 and the lower glass 130. The polarization layer 140 which is located below the cover glass (for example, the upper glass 160) is disposed above the lower glass 130 and a top of the polarization layer 140 may be covered by the upper glass 160. As the polarization layer 140 is disposed between the lower glass 130 and the upper glass 160, the polarization layer 140 may not be provided above the display panel 110 which is at a bottom of the dual glasses 130 and 160. However, the example embodiment of the present disclosure is not limited thereto and if necessary, an additional polarization layer 140 may be provided.

The display device may include a light shielding member 170. The light shielding member 170 may be disposed in the non-active area NA of the display panel 110. The non-active area NA in which the light shielding member 170 is located is referred to as a bezel area. The light shielding member 170 may overlap the driving circuit or the driving line of the non-active area NA. The light shielding member 170 may be disposed on a rear surface of the lower glass 130. The light shielding member 170 is disposed on the rear surface of the lower glass 130 in the non-active area NA to additionally shield light which is incident into the non-active area NA.

The light shielding member 170 performs various functions. The light shielding member 170 is located at the edge of the display device to improve an optical performance and enhance aesthetic elements. To be more specific, the light tends to be leaked from the edge of the display panel 110 and the light shielding member 170 blocks the light leakage to improve the contrast of the display device. Further, the light shielding member may reduce light reflection which may occur between components in the display device.

The light shielding member 170 is formed of various materials. The light shielding member 170 may be formed of a black ink. The black ink has a high light absorptance to effectively reduce light reflectance and make periphery of the display device dark and clean.

Ends of the upper glass 160 and the lower glass 130 are equal and ends of the adhesive member 150 and the polarization layer 140 may also be equal to the ends of the upper glass 160 and the lower glass 130. The end of the upper glass 160 may match the end of the lower glass 130. The end of the adhesive member 150 and the end of the polarization layer 140 may also match the end of the upper glass 160 and the end of the lower glass 130. For example, the end of the upper glass 160 and the end of the lower glass 130 may be disposed on the same plane. The end of the adhesive member 150 and the end of the polarization layer 140 may also be disposed on the same plane as the end of the upper glass 160 and the end of the lower glass 130.

The display device may include a housing adhesive member 180. Further, the display device may include a housing 190 which covers a bottom of the display panel 110. The housing 190 may be bonded to the dual glasses 130 and 160. To be more specific, the housing 190 may be bonded to the lower glass 130. The housing 190 and the lower glass 130 may be bonded by the housing adhesive member 180. The housing adhesive member 180 is located in the non-active area NA and the housing 190 may be bonded to the rear surface of the lower glass 130 in the non-active area NA.

In the meantime, even though in FIG. 4B, it is illustrated that the housing 190 is bonded to the rear surface of the lower glass 130 between the dual glasses 130 and 160, the housing 190 may be bonded to side surfaces of the dual glasses 130 and 160 depending on a design method. For example, the housing 190 may be bonded to the side surface of the lower glass 130, the side surface of the polarization layer 140, the side surface of the second adhesive member 150, and the side surface of the upper glass 160. At this time, the housing adhesive member 180 is disposed on side surfaces of the dual glasses 130 and 160 and the housing 190 is disposed on side surfaces of the dual glasses 130 and 160 on which the housing adhesive member 180 is disposed. That is, the housing 190 may be bonded to the side surfaces of the dual glasses 130 and 160 by the housing adhesive member 180, but is not limited thereto.

The display device 100 according to the example embodiment of the present disclosure includes a polarization layer 140 which is disposed not only in the active area AA, but also in the non-active area NA. Therefore, the boundary between the active area AA and the non-active area NA may be seamlessly implemented without increasing a surface reflectance. Accordingly, in the display device 100 according to the example embodiment of the present disclosure, a viewing screen of the display device 100 and a bezel area which encloses the viewing screen are included to provide a visibility which is substantially equal or uniform. Further, in the display device 100 according to the example embodiment of the present disclosure, the boundary between the active area AA and the non-active area NA may be seamlessly implemented while the display device 100 displays black.

The example embodiments of the present disclosure can also be described as follows:

According to an aspect of the present disclosure, a display device includes a display panel which includes a plurality of sub pixels; dual glasses which are disposed on the display panel and include an upper glass and a lower glass; and a polarization layer disposed between the upper glass and the lower glass, the dual glasses include an active area and a non-active area and the polarization layer may be disposed from the active area to the non-active area.

The plurality of sub pixels may be disposed in the active area.

The display device may further comprise a light shielding member disposed on a rear surface of the lower glass.

The light shielding member may be disposed in the non-active area.

In the non-active area, the polarization layer may be disposed above the light shielding member.

There may be no additional polarization layer between the light shielding member and the display panel.

The display device may further comprise a sensor layer disposed above the display panel.

The sensor layer may be bonded to the lower glass.

The upper glass may be bonded to the polarization layer.

The display device may further comprise a housing which covers a lower portion of the display panel.

The housing may be bonded to a rear surface of the lower glass in the non-active area.

A strength of the upper glass may be higher than a strength of the lower glass.

A thickness of the upper glass may be larger than a thickness of the lower glass.

An end of the upper glass and an end of the lower glass may be disposed on the same plane.

An end of the polarization layer may be disposed on the same plane as the end of the upper glass and the end of the lower glass.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims and their equivalents, and all the technical concepts in the equivalent scope thereof should be construed as falling within the scope of the present disclosure.

What is claimed is:

1. A display device, comprising:
a display panel including a plurality of sub pixels;
dual glasses disposed on the display panel and including an upper glass and a lower glass; and
a polarization layer disposed between the upper glass and the lower glass,
wherein the dual glasses include an active area and a non-active area, and
wherein the polarization layer is disposed from the active area to the non-active area.

2. The display device according to claim 1, wherein the plurality of sub pixels is disposed in the active area.

3. The display device according to claim 1, further comprising:
a light shielding member disposed on a rear surface of the lower glass.

4. The display device according to claim 3, wherein the light shielding member is disposed in the non-active area.

5. The display device according to claim 3, wherein in the non-active area, the polarization layer is disposed above the light shielding member.

6. The display device according to claim 3, wherein there is no additional polarization layer between the light shielding member and the display panel.

7. The display device according to claim 1, further comprising:
a sensor layer disposed above the display panel.

8. The display device according to claim 7, wherein the sensor layer is bonded to the lower glass.

9. The display device according to claim 1, wherein the upper glass is bonded to the polarization layer.

10. The display device according to claim 1, further comprising:
a housing which covers a lower portion of the display panel.

11. The display device according to claim 10, wherein the housing is bonded to a rear surface of the lower glass in the non-active area.

12. The display device according to claim 1, wherein a strength of the upper glass is higher than a strength of the lower glass.

13. The display device according to claim 1, wherein a thickness of the upper glass is larger than a thickness of the lower glass.

14. The display device according to claim 1, wherein an end of the upper glass and an end of the lower glass are disposed on a same plane.

15. The display device according to claim 14, wherein an end of the polarization layer is disposed on the same plane as the end of the upper glass and the end of the lower glass.
